(19) United States
(12) Patent Application Publication
(10) Pub. No.: US 2025/0227909 A1
(43) Pub. Date: Jul. 10, 2025

(54) STATIC RANDOM-ACCESS MEMORY CELL

(71) Applicant: SAMSUNG ELECTRONICS CO., LTD., SUWON-SI (KR)

(72) Inventors: EOJIN LEE, Suwon-si (KR); YONGRAE CHO, Suwon-si (KR); BOMI CHOI, Suwon-si (KR); TAE-HYUNG KIM, Suwon-si (KR); SUNME LIM, Suwon-si (KR)

(21) Appl. No.: 18/809,726

(22) Filed: Aug. 20, 2024

(30) Foreign Application Priority Data
Jan. 9, 2024 (KR) 10-2024-0003414

(51) Int. Cl. H10B 10/00

(52) U.S. Cl. CPC H10B 10/125

(57) ABSTRACT

A semiconductor device may include a first gate electrode controlling a first pull-down transistor and a first pull-up transistor, a second gate electrode controlling a second pull-down transistor and a second pull-up transistor, a third pull-down transistor, a third pass transistor connected in series with the third pull-down transistor, a first node active contact connecting a drain terminal of the second pull-up transistor and a drain terminal of the second pull-down transistor, a first gate contact connecting a gate terminal of the third pull-down transistor and the first node active contact, and a second gate contact connecting a gate terminal of the first pull-up transistor and a gate terminal of the first pull-down transistor to the first node active contact.

### CROSS-REFERENCE TO RELATED APPLICATIONS

This patent application claims priority under 35 U.S.C. § 119 to Korean Patent Application No. 10-2024-0003414, filed on Jan. 9, 2024, in the Korean Intellectual Property Office, the entire contents of which are hereby incorporated by reference.

### TECHNICAL FIELD

The present disclosure relates to a semiconductor device, and more particularly, relates to a semiconductor device including an SRAM cell.

### DISCUSSION OF RELATED ART

A semiconductor device may include an integrated circuit including metal-oxide-semiconductor field effect transistors (MOSFETs). As sizes and design rules of semiconductor devices have been reduced, sizes of the MOSFETs have also been scaled down. Operating characteristics of semiconductor devices may be deteriorated by the scale down of the MOSFETs. Thus, various research is being conducted into semiconductor devices capable of achieving high integration and improved performance.

### SUMMARY

An embodiment of the inventive concept is to provide to a semiconductor device with improved reliability and increased integration density.

Aspects of the inventive concept are not limited to those described herein, and other aspects not mentioned will be clearly understood by those skilled in the art from the description below.

According to some embodiments of the inventive concept, a semiconductor device may include a first gate electrode controlling a first pull-down transistor and a first pull-up transistor, a second gate electrode controlling a second pull-down transistor and a second pull-up transistor, a third pull-down transistor, a third pass transistor connected in series with the third pull-down transistor, a first node active contact connecting a drain terminal of the second pull-up transistor and a drain terminal of the second pull-down transistor, a first gate contact connecting a gate terminal of the third pull-down transistor and the first node active contact, and a second gate contact connecting a gate terminal of the first pull-up transistor and a gate terminal of the first pull-down transistor to the first node active contact.

According to some embodiments of the inventive concept, a semiconductor device may include a first port including a first inverter, a second inverter cross-connected to the first inverter, a first pass transistor connected between a bit line and an input node of the first inverter, and a second pass transistor connected between a complementary bit line and an input node of the second inverter, and a second port including a read pull-down transistor having a gate connected to the input node of the first inverter and an output node of the second inverter, and a third pass transistor connected between the pull-down transistor and a read bit line.

According to some embodiments of the inventive concept, semiconductor device may include a semiconductor substrate including a first active region and a second active region, a first active pattern and a second active pattern disposed on the first active region, a third active pattern, a fourth active pattern, and a fifth active pattern disposed on the second active region, wherein the third active pattern and the fourth active pattern are spaced apart from each other in a first direction with the first active pattern and the second active pattern interposed therebetween, and the fifth active pattern is disposed on a side of the fourth active pattern, a first gate electrode crossing the first active pattern and the third active pattern and having a first length in the first direction, a second gate electrode crossing the second active pattern and the fourth active pattern and having a second length substantially equal to the first length in the first direction, a third gate electrode spaced apart from the second gate electrode in the first direction and crossing the third active pattern, a fourth gate electrode spaced apart from the first gate electrode in the first direction and crossing the fourth active pattern, a fifth gate electrode spaced apart from the second gate electrode in the first direction and crossing the fifth active pattern, a sixth gate electrode spaced apart from the fourth gate electrode in the first direction and crossing the fifth active pattern, a first node active contact connected to source/drain patterns on the second active pattern and the fourth active pattern disposed between the first gate electrode and the second gate electrode, a first gate contact connecting the first gate electrode and the first node active contact, and a second gate contact connecting the fifth gate electrode and the first node active contact.

Embodiments are described in detail in the detailed description with reference to the drawings.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a circuit diagram showing an SRAM cell of a semiconductor device according to embodiments of the inventive concept.

FIG. 2 is a plan view showing a portion of a semiconductor device according to embodiments of the inventive concept.

FIG. 3 is a plan view showing a portion of a semiconductor device according to embodiments of the inventive concept.

FIG. 4 is a plan view showing a portion of a semiconductor device according to embodiments of the inventive concept.

FIG. 5 is a cross-sectional view of a semiconductor device according to embodiments of the inventive concept, taken along line A-A′ of FIG. 4.

FIG. 6 is a cross-sectional view of a semiconductor device according to embodiments of the inventive concept, taken along line B-B′ of FIG. 4.

FIG. 7 is a cross-sectional view of a semiconductor device according to embodiments of the inventive concept, taken along line C-C′ of FIG. 4.

FIG. 8 is a cross-sectional view of a semiconductor device according to embodiments of the inventive concept, taken along line D-D′ of FIG. 4.

FIG. 9 is a cross-sectional view of a semiconductor device according to embodiments of the inventive concept, taken along line A-A′ of FIG. 4.

FIG. 10 is a cross-sectional view of a semiconductor device according to embodiments of the inventive concept, taken along line C-C′ of FIG. 4.

FIG. 11 is a cross-sectional view of a semiconductor device according to embodiments of the inventive concept taken in line D-D′ of FIG. 4.

FIG. 12 is a plan view showing a semiconductor device according to embodiments of the inventive concept.

### DETAILED DESCRIPTION

Hereinafter, a semiconductor device according to embodiments of the inventive concept will be described in detail with reference to the drawings. The inventive concepts may be implemented in various modifications and have various forms, and specific embodiments are illustrated in the drawings and described in detail in the text. It is to be understood, however, that the inventive concepts are not intended to be limited to the particular forms disclosed, but on the contrary, is intended to cover all modifications, equivalents, and alternatives falling within the spirit and scope of the inventive concepts.

Like reference numerals or symbols refer to like elements throughout. In the drawings, the thickness, the ratio, and the dimension of the elements may be exaggerated for effective description of the technical contents.

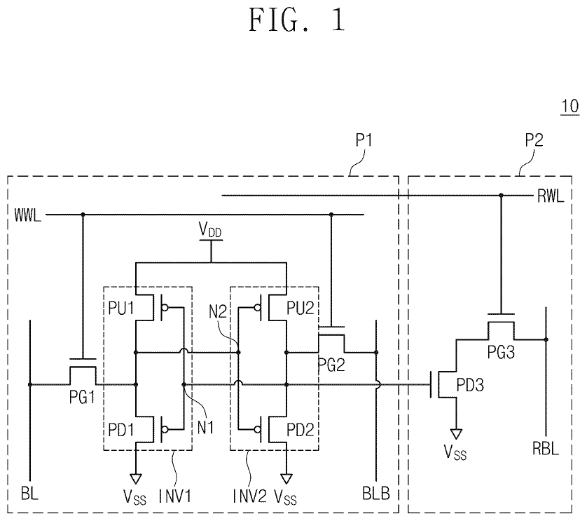

FIG. 1 is a circuit diagram showing a Static Random-Access Memory (SRAM) cell of a semiconductor device according to embodiments of the inventive concept.

Referring to FIG. 1, an SRAM cell 10 according to embodiments of the inventive concept may include a first port P1 and a second port P2. The first port P1 may be a write port for writing data, and the second port P2 may be a read port for reading data.

The first port P1 of the SRAM cell 10 may include a first inverter INV1, a second inverter INV2, a first pass transistor PG1, and a second pass transistor PG2.

The first inverter INV1 and the second inverter INV2 may be connected between a power node VDD and a ground node VSS. The first inverter INV1 may include a first pull-up transistor PU1 and a first pull-down transistor PD1. The first pull-up transistor PU1 and the first pull-down transistor PD1 may be connected in series. The second inverter INV2 may include a second pull-up transistor PU2 and a second pull-down transistor PD2. The second pull-up transistor PU2 and the second pull-down transistor PD2 may be connected in series.

The first pull-up transistor PU1 and the second pull-up transistor PU2 may be PMOS transistors, and the first pull-down transistor PD1 and the second pull-down transistor PD2 may be NMOS transistors.

An input node (i.e., a first node N1) of the first inverter INV1 may be connected to an output node N3 of the second inverter INV2, and an input node (i.e., a second node N2) of the second inverter INV2 may be connected to an output node N4 of the first inverter INV1. For example, the second inverter may be cross-coupled to the first inverter. In detail, a gate of the first pull-up transistor PU1 and a gate of the first pull-down transistor PD1 may be connected to a drain of the second pull-up transistor PU2 and a drain of the second pull-down transistor PD2. That is, the gates of the first pull-up and first pull-down transistors PU1 and PD1 and the drains of the second pull-up and second pull-down transistors PU2 and PD2 may be commonly connected to the first node N1. A gate of the second pull-up transistor PU2 and a gate of the second pull-down transistor PD2 may be connected to a drain of the first pull-up transistor PU1 and a drain of the first pull-down transistor PD1. That is, the gates of the second pull-up and second pull-down transistors PU2 and PD2 and the drains of the first pull-up and first pull-down transistors PU1 and PD1 may be connected to the second node N2. Accordingly, the first inverter INV1 and the second inverter INV2 may form a latch circuit. The latch circuit may store bits. For example, complementary values of the bits may be stored in the first node N1 and the second node N2. The stored bits may be written to the SRAM cell 10 through a bit line BL and a complementary bit line BLB.

The first pass transistor PG1 may be connected to an output node of the first inverter INV1. The second pass transistor PG2 may be connected to an output node of the second inverter INV2. In detail, the first pass transistor PG1 may be connected between the output node of the first inverter INV1 and the bit line BL, and the second pass transistor PG2 may be connected between the output node of the second inverter INV2 and the complementary bit line BLB. A gate of the first pass transistor PG1 and a gate of the second pass transistor PG2 may both be connected to a write word line WWL.

The second port P2 of the SRAM cell may include a third pass transistor PG3 and a third pull-down transistor PD3. The third pass transistor PG3 and the third pull-down transistor PD3 may be connected in series to each other.

A gate of the third pull-down transistor PD3 may be connected to the input node of the first inverter INV1 and the output node of the second inverter INV2. That is, the gate of the third pull-down transistor PD3 may be connected to the first node N1.

The third pull-down transistor PD3 may be connected between a ground node VSS and the third pass transistor PG3. The third pass transistor PG3 may be connected between the third pull-down transistor PD3 and a read bit line RBL. The gate of the third pass transistor PG3 may be connected to a read word line RWL. For example, the third pull-down transistor PD3 may be a read pull-down transistor.

The SRAM cell 10 according to embodiments may operate in a read operation mode or a write operation mode.

In the read operation mode, the read word line RWL may control the third pass transistor PG3, and the read bit line RBL connected to the third pull-down transistor PD3 may be activated to load a value stored in the SRAM cell 10. In the write operation mode, the write word line WWL may control the first pass transistor PG1 and the second pass transistor PG2, and the bit line BL connected to the first pass transistor PG1 and the complementary bit line BLB connected the second pass transistor PG2 may be activated to store a specific value. However, the inventive concept is not limited thereto.

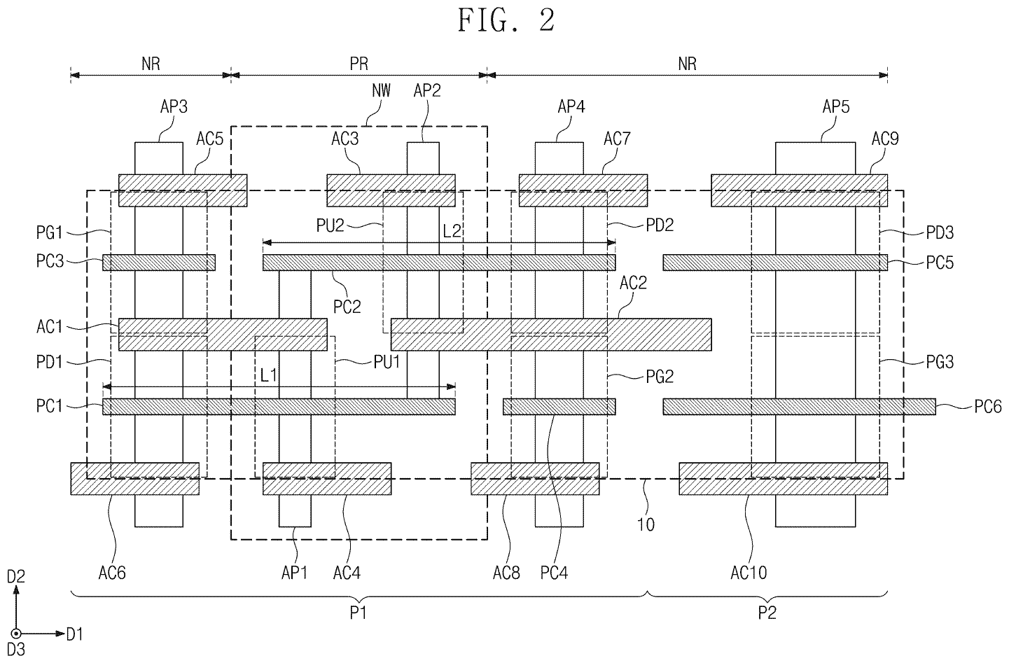

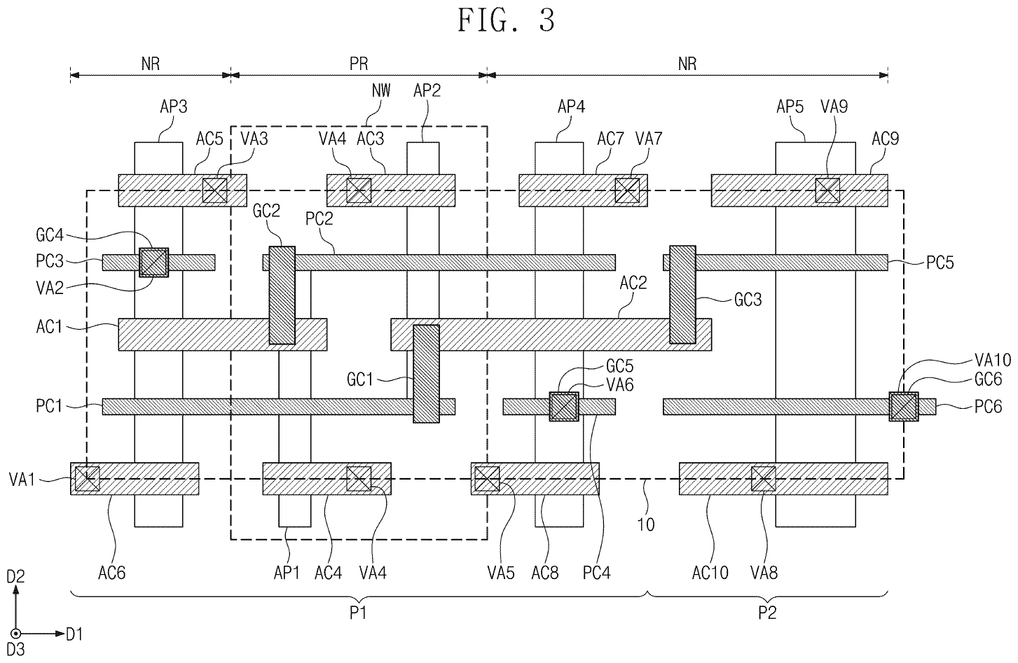

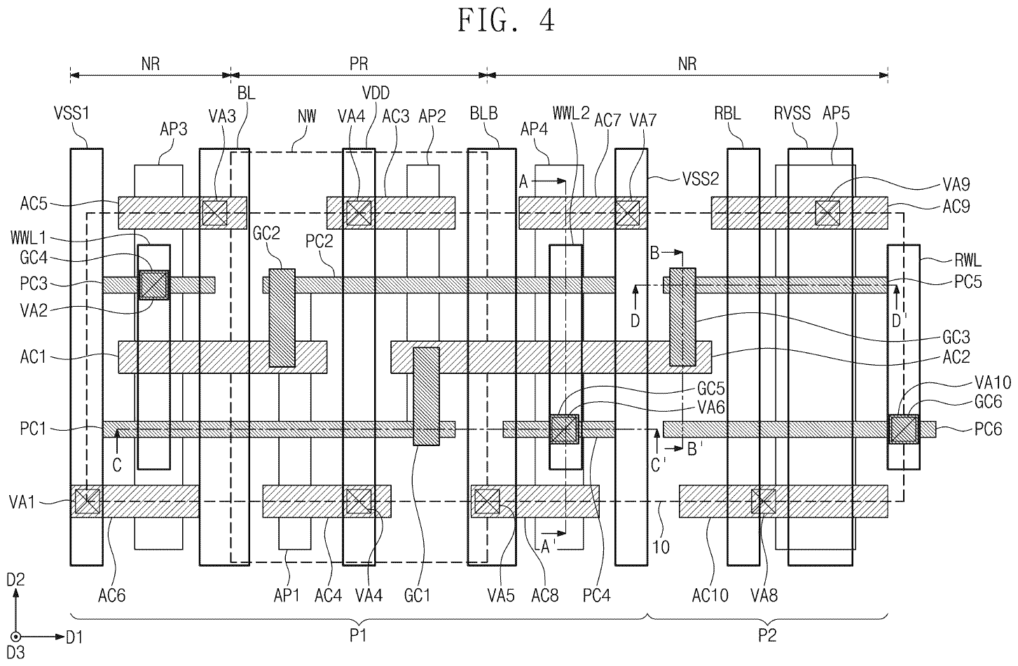

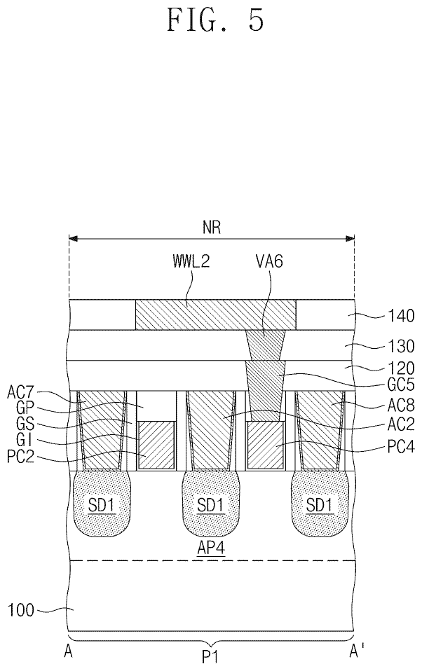

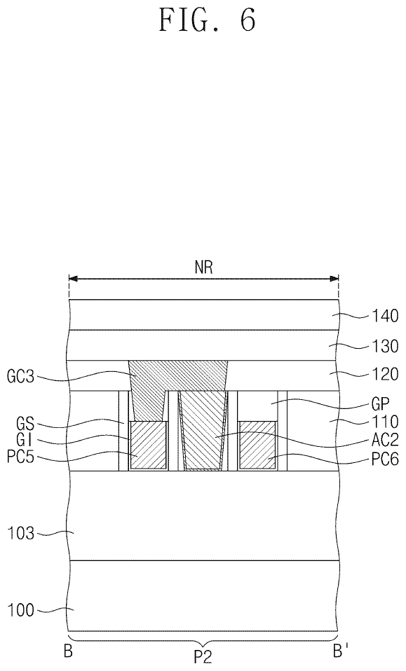

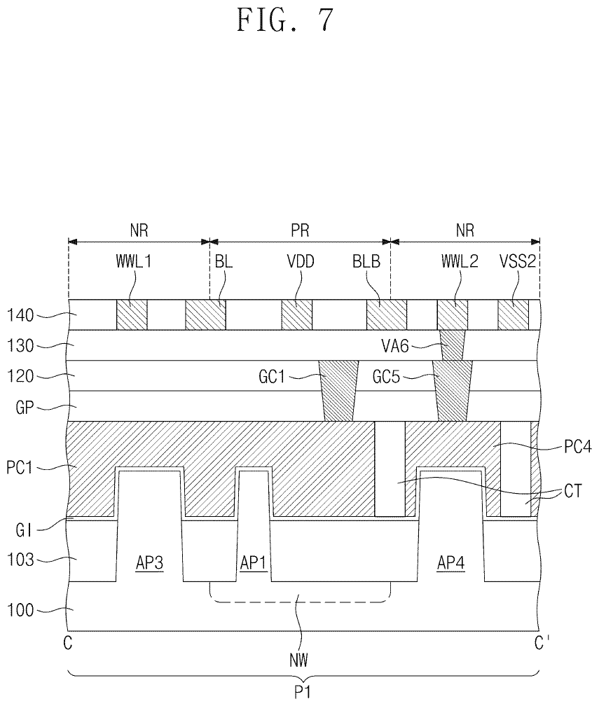

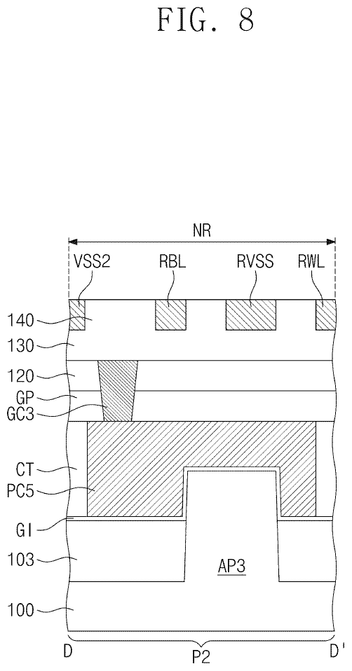

FIG. 2, FIG. 3, and FIG. 4 are plan views showing portions of semiconductor devices according to embodiments of the inventive concept. FIG. 5, FIG. 6, FIG. 7, and FIG. 8 are cross-sectional views of semiconductor devices according to embodiments of the inventive concept, taken along lines A-A′, B-B′, C-C′, and D-D′ of FIG. 4, respectively.

Referring to FIG. 2, FIG. 5, FIG. 6, FIG. 7, and FIG. 8, the SRAM cell 10 may be integrated on a semiconductor substrate 100, and the SRAM cell 10 may include a first port P1 and a second port P2, as described with reference to FIG. 1.

The semiconductor substrate 100 may be a bulk silicon substrate, a silicon-on-insulator (SOI) substrate, a germanium substrate, a germanium-on-insulator (GOI) substrate, a silicon-germanium substrate, or may be a substrate of an epitaxial thin layer obtained by performing selective epitaxial growth (SEG). As another example, the semiconductor substrate 100 may be a group III-V compound semiconductor substrate. The group III-V compound semiconductor substrate may include, for example, at least one of gallium arsenide (GaAs), indium gallium arsenide (InGaAs), or aluminum gallium arsenide (AlGaAs), or mixtures thereof. In some embodiments, the semiconductor substrate 100 may be a bulk silicon substrate doped with n-type impurities or p-type impurities.

The semiconductor substrate 100 may include a first active region PR (e.g., PMOS region) and a second active region NR (e.g., NMOS region). The semiconductor substrate 100 may include a semiconductor device in the first active region PR. A well region NW doped with n-type impurities may be disposed in the semiconductor substrate 100. The well region NW may extend in a second direction D2.

The semiconductor substrate 100 may include a first active pattern AP1, a second active pattern AP2, a third active pattern AP3, a fourth active pattern AP4, and a fifth active pattern AP5. The first to fifth active patterns AP1, AP2, AP3, AP4, and AP5 may be arranged to be spaced apart from each other in a first direction D1 and may extend in the second direction D2. The first to fifth active patterns AP1, AP2, AP3, AP4, and AP5 may be portions of the semiconductor substrate 100 and may be vertically protruding portions extending in a third direction D3. The first direction D1 and the second direction D2 may intersect and form a plane. The third direction D3 may be perpendicular to the plane formed by the first direction D1 and the second direction D2.

Device isolation patterns 103 may be disposed between the first to fifth active patterns AP1, AP2, AP3, AP4, and AP5. Upper surfaces of the device isolation patterns 103 may be disposed below the upper surfaces of the first to fifth active patterns AP1, AP2, AP3, AP4, and AP5. The first to fifth active patterns AP1, AP2, AP3, AP4, and AP5 may protrude above the upper surfaces of the device isolation patterns 103.

The first and second active patterns AP1 and AP2 may be disposed in the first active region PR. That is, the first and second active patterns AP1 and AP2 may be disposed on the well region NW. Each of the first and second active patterns AP1 and AP2 may have a first width in the first direction D1. The first and second active patterns AP1 and AP2 may have a length in the second direction D2 that is less than a length of the third, fourth, and fifth active patterns AP3, AP4, and AP5 in the second direction D2. The first and second active patterns AP1 and AP2 may be arranged in the second direction D2 to be offset from each other. For example, portions of lengths of the first and second active patterns AP1 and AP2 in the second direction D2 may not overlap in the first direction D1.

The third and fourth active patterns AP3 and AP4 may be disposed in the second active region NR on sides of the well region NW. Each of the third and fourth active patterns AP3 and AP4 may have a second width greater than the first width in the first direction D1. As an example, the second width may be about 1.5 to 2 times the first width.

The fifth active pattern AP5 may be disposed in the second active region NR. The fifth active pattern AP5 may be disposed on a side of the fourth active pattern AP4. The fifth active pattern AP5 may have a third width greater than the second width in the first direction D1.

A first gate electrode PC1, a second gate electrode PC2, a third gate electrode PC3, a fourth gate electrode PC4, a fifth gate electrode PC5, and a sixth gate electrode PC6 may each have a long axis in the first direction D1. The first to sixth date electrodes PC1, PC2, PC3, PC4, PC5, and PC6 may be spaced apart from each other.

For example, the first, fourth, and sixth gate electrodes PC1, PC4, and PC6 may be arranged along the first direction D1, and the second, third, and fifth gate electrodes PC2, PC3, and PC5 may be arranged along the first direction D1, and the first, fourth, and sixth gate electrodes PC1, PC4, and PC6 and the second, third, and fifth gate electrodes PC2, PC3, and PC5 may be spaced apart from each other in the second direction D2. The second, third, and fifth gate electrodes PC2, PC3, and PC5 may be arranged to be spaced apart from each other at regular intervals in the first direction D1. The first, fourth, and sixth gate electrodes PC1, PC4, and PC6 may be arranged to be spaced apart from each other at regular intervals in the first direction D1.

The first gate electrode PC1 may be disposed across the first active pattern AP1, the second active pattern AP2, and the third active pattern AP3, and may have a first length L1 in the first direction D1.

The second gate electrode PC2 may be disposed across the first active pattern AP1, the second active pattern AP2, and the fourth active pattern AP4, and may have a second length L2 in the first direction D1. Here, the second length L2 may be substantially equal to the first length L1.

The third gate electrode PC3 may be spaced apart from the first gate electrode PC1 in the second direction D2 and may be disposed across the third active pattern AP3.

The fourth gate electrode PC4 may be spaced apart from the second gate electrode PC2 in the second direction D2 and may be disposed across the fourth active pattern AP4.

The fifth and sixth gate electrodes PC5 and PC6 may be spaced apart from each other in the second direction D2 and may be disposed across the fifth active pattern AP5. The fifth and sixth gate electrodes PC5 and PC6 may have different lengths in the first direction D1, or may have the same length.

The first to sixth gate electrodes PC1 to PC6 may include, for example, a barrier metal pattern and a metal pattern. The barrier metal pattern may include a conductive metal nitride (e.g., titanium nitride, tantalum nitride, and/or tungsten nitride). The metal pattern may include a metallic material (e.g., tungsten, aluminum, titanium, and/or tantalum).

Gate separation patterns CT may be disposed between the first, fourth, and sixth gate electrodes PC1, PC4, and PC6 spaced apart in the first direction D1 (see for example, FIG. 7). Additionally, the gate separation patterns CT may be disposed between the second, third, and fifth gate electrodes PC2, PC3, and PC5 spaced apart in the first direction D1 (see for example, FIG. 8).

A gate insulating layer GI may be disposed on an upper surface of the device isolation pattern 103 and upper portions of the first to fifth active patterns AP1 to AP5. For example, the gate insulating layer GI may be disposed between the first to sixth gate electrodes PC1 to PC6 and the first to fifth active patterns AP1 to AP5. The gate insulating layer GI may cover the upper surface of the device isolation pattern 103 below the first to sixth gate electrodes PC1 to PC6.

The gate insulating layer GI may include a silicon oxide layer, a silicon oxynitride layer, and/or a high-k dielectric layer. The high dielectric layer may include a high dielectric constant material that has a higher dielectric constant than the silicon oxide layer. As an example, the high dielectric constant material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, and strontium titanium. oxide, lithium oxide, aluminum oxide, lead scandium tantalum oxide, or lead zinc niobate.

A pair of gate spacers GS may be disposed on side walls of each of the first to sixth gate electrodes PC1 to PC6. The gate spacers GS may extend in the first direction D1 along the first to sixth gate electrodes PC1 to PC6. Upper surfaces of the gate spacers GS may be higher than upper surfaces of the first to sixth gate electrodes PC1 to PC6. The upper surfaces of the gate spacers GS may be coplanar with an upper surface of a first interlayer insulating layer 110 (see for example, FIG. 6). The gate spacers GS may include at least one of SiCN, SiCON, or SiN. As another example, the gate spacers GS may include a multi-layer made of at least two of SiCN, SiCON, and SiN.

A gate capping pattern GP may be disposed on each of the first to sixth gate electrodes PC1 to PC6. The gate capping pattern GP may extend in the first direction D1 in the first to sixth gate electrodes PC1 to PC6. The gate capping pattern GP may include a material that has etch selectivity with respect to the first interlayer insulating layer 110 and a second interlayer insulating layer 120. In detail, the gate capping pattern GP may include at least one of SiON, SiCN, SiCON, or SiN.

First source/drain patterns SD1 may be disposed on the third, fourth, and fifth active patterns AP3, AP4, and AP5. Second source/drain patterns (now shown) may be disposed on the first and second active patterns AP1 and AP2. The second source/drain patterns may include impurities of a different conductivity type than the first source/drain patterns SD1. The first source/drain patterns SD1 and the second source/drain patterns may include silicon carbide or silicon germanium. The first source/drain patterns SD1 and the second source/drain patterns may be epitaxial patterns formed through a selective epitaxial growth (SEG) process.

The semiconductor device may include a plurality of active contacts. For example, the semiconductor device may include a first active contact AC1, a second active contact AC2, a third active contact AC3, a fourth active contact AC4, a fifth active contact AC5, a sixth active contact AC6, a seventh active contact AC7, an eighth active contact AC8, a nineth active contact AC9 and a tenth active contact AC10. The first to tenth active contacts AC1 to AC10 may each have a bar shape extending in the second direction D2 and may be connected to the first second source/drain patterns SD1 and/or the second source/drain patterns.

The first to tenth active contacts AC1 to AC10 may penetrate the first interlayer insulating layer 110 and be connected to the first source/drain patterns SD1 and/or the second source/drain patterns. Upper surfaces of the first to tenth active contacts AC1 to AC10 may be coplanar with the upper surface of the first interlayer insulating layer 110.

The first and second active contacts AC1 and AC2 may be arranged to be spaced apart from each other in the first direction D1. The first and second active contacts AC1 and AC2 may be disposed between the first and second gate electrodes PC1 and PC2.

The first active contact AC1 may cross the first active pattern AP1 and the third active pattern AP3. The first active contact AC1 may connect the second source/drain pattern on the first active pattern AP1 and the first source/drain pattern SD1 on the third active pattern AP3. The first active contact AC1 may connect the drain of the first pull-up transistor PU1 and the drain of the first pull-down transistor PD1 described with reference to FIG. 1, and may also be referred to as a first node active contact.

The second active contact AC2 may cross the second and fourth active patterns AP2 and AP4. The second active contact AC2 may connect the second source/drain pattern on the second active pattern AP2 and the first source/drain pattern on the fourth active pattern AP4. The second active contact AC2 may have a longer length in the first direction D1 than the first active contact AC1. The second active contact AC2 may connect the drain of the second pull-up transistor PU2 and the drain of the second pull-down transistor PD2 described with reference to FIG. 1, and may also be referred to as a second node active contact.

The third active contact AC3 may be spaced apart from the second active contact AC2 in the second direction D2. The third active contact AC3 may be disposed on the second active pattern AP2. The third active contact AC3 may overlap a portion of the second active contact AC2 in the first direction D1.

The fourth active contact AC4 may be disposed on the first active pattern AP1. The fourth active contact AC4 may be spaced apart from the first active contact AC1 in the second direction D2. The fourth active contact AC4 may overlap a portion of the first active contact AC1 in the first direction D1.

The fifth and sixth active contacts AC5 and AC6 may be spaced apart from the first active contact AC1 in the second direction D2 and may be disposed on the third active pattern AP3. For example, the first active contact AC1 may be disposed between the fifth and sixth active contacts AC5 and AC6.

The seventh and eighth active contacts AC7 and AC8 may be disposed on the fourth active pattern AP4 and spaced apart from the second active contact AC2 in the second direction D2. For example, the second active contact AC2 may be disposed between the seventh and eighth active contacts AC7 and AC8.

The ninth and tenth active contacts AC9 and AC10 may be spaced apart from each other in the second direction D2. The fifth and sixth gate electrodes PC5 and PC6 may be interposed between the ninth and tenth active contacts AC9 and AC10. The ninth and tenth active contacts AC9 and AC10 may be connected to the first source/drain patterns SD1 on the fifth active pattern AP5.

The fifth, third, seventh, and ninth active contacts AC5, AC3, AC7, and AC9 may be arranged to be spaced apart from each other in the first direction D1. The sixth, fourth, eighth, and tenth active contacts AC6, AC4, AC8, and AC10 may be arranged to be spaced apart from each other in the first direction D1.

The first to tenth active contacts AC1 to AC10 may include a barrier metal pattern and a metal pattern. The first to tenth active contacts AC1 to AC10 may include, for example, a metal such as tungsten, titanium, tantalum, or cobalt, and/or conductive metal nitride such as titanium nitride, tantalum nitride, or tungsten nitride.

The first to tenth active contacts AC1 to AC10 may be self-aligned contacts. That is, the first to tenth active contacts AC1 to AC10 may be formed in a self-aligned manner that may use the gate capping pattern GP and the gate spacer GS. A metal silicide pattern may be interposed between the first to tenth active contacts AC1 to AC10 and the first and second source/drain patterns, respectively.

First to sixth gate electrodes PC1 to PC6 and the first to tenth active contacts AC1 to AC10 may form the transistors described with reference to FIG. 1.

In detail, the first gate electrode PC1 and the first and fourth active contacts AC1 and AC4 may form the first pull-up transistor PU1 of FIG. 1. The first gate electrode PC1 and the first and sixth active contacts AC1 and AC6 may form the first pull-down transistor PD1 of FIG. 1.

The second gate electrode PC2 and the second and third active contacts AC2 and AC3 may form the second pull-up transistor PU2 of FIG. 1. The second gate electrode PC2 and the second and seventh active contacts AC2 and AC7 may form the second pull-down transistor PD2 of FIG. 1.

The third gate electrode PC3 and the first and fifth active contacts AC1 and AC5 may form the first pass transistor PG1 of FIG. 1. The fourth gate electrode PC4 and the second and eighth active contacts AC2 and AC8 may form the second pass transistor PG2 of FIG. 1.

The fifth gate electrode PC5, the ninth active contact AC9, and the first source/drain pattern SD1 disposed between the fifth gate electrode PC5 and the sixth gate electrode PC6 may form the third pull-down transistor PD3 of FIG. 1.

The sixth gate electrode PC6, the tenth active contact AC10, and the first source/drain pattern SD1 disposed between the fifth gate electrode PC5 and the sixth gate electrode PC6 may form the third pass transistor PG3 of FIG. 1.

According to an embodiment, the first and fourth gate electrodes PC1 and PC4 and the second and third gate electrodes PC2 and PC3 may be disposed symmetrically to each other in the first port P1 of the SRAM cell 10. Accordingly, the transistors forming the first inverter INV1 and the second inverter INV2 described with reference to FIG. 1 may have substantially the same operating characteristics. That is, the first pull-down transistor PD1 and the second pull-down transistor PD2 may be inhibited or prevented from having asymmetric operation characteristics, for example, having different threshold voltages.

Referring to FIG. 3, FIG. 5, FIG. 6, FIG. 7, and FIG. 8, a first gate contact GC1 may connect the first gate electrode PC1 and the second active contact AC2. Accordingly, the input node of the first inverter INV1 may be connected to the output node of the second inverter INV2 (see FIG. 1).

A second gate contact GC2 may connect the second gate electrode PC2 and the first active contact AC1. Accordingly, the input node of the second inverter INV2 may be connected to the output node of the first inverter INV1 (see FIG. 1).

Referring to FIG. 3, the first gate electrode PC1 and the first gate contact GC1 may be disposed symmetrical with the second gate electrode PC2 and the second gate contact GC2.

The third gate contact GC3 may connect the fifth gate electrode PC5 and the second active contact AC2. Accordingly, the gate of the third pull-down transistor PD3 (e.g., in FIG. 1) of the second port P2 may be connected to the first node N1 (e.g., in FIG. 1).

According to embodiments, the first gate electrode PC1 of the first port P1 may be electrically connected to the fifth gate electrode PC5 of the second port P2 through the first gate contact GC1, the second active contact AC2, and the third gate contact GC3. That is, the input node of the first inverter INV1 and the gate of the third pull-down transistor PD3 may be electrically connected to the first gate contact PD3 (see FIG. 1) through the first gate contact GC1, the second active contact AC2, and the third gate contact GC3 (see FIG. 3).

The first, second, and third gate contacts GC1, GC2, and GC3 may have a bar shape with a long axis substantially parallel to the second direction D2. As shown in FIG. 6, each of the first, second, and third gate contacts GC1, GC2, and GC3 may include a lower portion that penetrates the gate capping pattern GP and an upper portion in the second interlayer insulating layer 120. For example, the first gate contact GC1 may be in contact with an upper surface of the first gate electrode PC1, the second gate contact GC2 may be in contact with an upper surface of the second gate electrode PC2, and the third gate contact GC4 may be in contact with an upper surface of the fifth gate electrode PC5. A lower surface of an upper portion of the first, second, and third gate contacts GC1, GC2, and GC3 may be in contact with the upper surfaces of the first or second active contacts AC1 and AC2. The upper portion of each of the first, second, and third gate contacts GC1, GC2, and GC3 may extend in the second direction D2 to connect between a respective gate electrode/active contact pair (see FIG. 6). Upper surfaces of the first, second, and third gate contacts GC1, GC2, and GC3 may be substantially coplanar with the upper surface of the second interlayer insulating layer 120.

The fourth, fifth, and sixth gate contacts GC4, GC5, and GC6 penetrate the second interlayer insulating layer 120 and the capping insulating pattern GP to be connected to the third, fourth, and sixth gate electrodes PC3, PC4, and PC6, respectively.

Each of the first to sixth gate contacts GC1 to GC6 may include a barrier metal pattern and a metal pattern, substantially similar to the first to tenth active contacts AC1 to AC10.

A first via VA1 may penetrate the third interlayer insulating layer 130 to be connected to the sixth active contact AC6, and a second via VA2 may penetrate the third interlayer insulating layer 130 to be connected to the fourth gate contact GC4 (see FIG. 4).

A third via VA3 may penetrate the third interlayer insulating layer 130 to be connected to the fifth active contact AC5, and fourth vias VA4 may penetrate the third interlayer insulating layer 130 to be connected to the third and the fourth active contacts AC3 and AC4, respectively.

A fifth via VA5 may penetrate the third interlayer insulating layer 130 to be connected to the eighth active contact AC8, and a sixth via VA6 may penetrate the third interlayer insulating layer 130 to be connected to the fifth gate contact GC5 (see FIG. 5).

A seventh via VA7 may penetrate the third interlayer insulating layer 130 to be connected to the seventh active contact AC7, and an eighth via VA8 may penetrate the third interlayer insulating layer 130 to be connected to the tenth active contact AC10.

A ninth via VA9 may penetrate the third interlayer insulating layer 130 to be connected to the ninth active contact AC9, and a tenth via VA10 may penetrate the third interlayer insulating layer 130 to be connected to the sixth gate contact GC6.

Referring to FIG. 4, FIG. 5, FIG. 6, FIG. 7, and FIG. 8, metal wiring lines extending in the second direction D2 and spaced apart from each other in the first direction D1 may be disposed in a fourth interlayer insulating layer 140. The metal wiring lines may include a bit line BL, a complementary bit line BLB, a read bit line RBL, a read word line RWL, a power line VDD, a first ground line VSS1, a second ground line VSS2, and a read ground line RVSS.

Metal wiring patterns having a long axis in the second direction D2 may be disposed in the fourth interlayer insulating layer 140, and the metal wiring patterns may include a first write word line WWL1, a second write word line WWL2, and the read word line RWL.

The first ground line VSS1 may be connected to the first via VA1. The first ground line VSS1 may be disposed at a boundary of the SRAM cell 10.

The bit line BL may be connected to the third via VA3. The bit line BL may be disposed between the first active pattern AP1 and the third active pattern AP3.

The power line VDD may be connected to the fourth vias VA4. The power line VDD may electrically connect the third and fourth active contacts AC3 and AC4. The power line VDD may be disposed between the first and second active patterns AP1 and AP2.

The complementary bit line BLB may be connected to the fifth via VA5. The complementary bit line BLB may be disposed between the second active pattern AP2 and the fourth active pattern AP4.

The second ground line VSS2 may be connected to the seventh via VA7 The read bit line RBL may be connected to the eighth via VA8. The read ground line RVSS may be connected to the ninth via VA9.

The first write word line WWL1 may be connected to the second via VA2 disposed between the first ground line VSS1 and the bit line BL. The second write word line WWL2 may be connected to the sixth via VA6 disposed between the second ground line VSS2 and the complementary bit line BLB.

The read word line RWL may be connected to the tenth via VA10 at an edge of the SRAM cell 10.

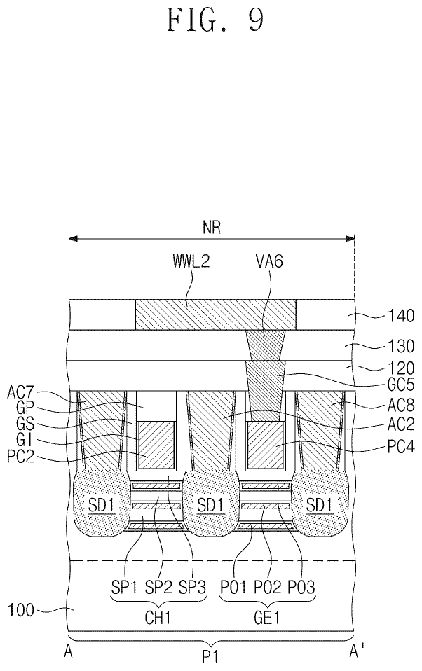

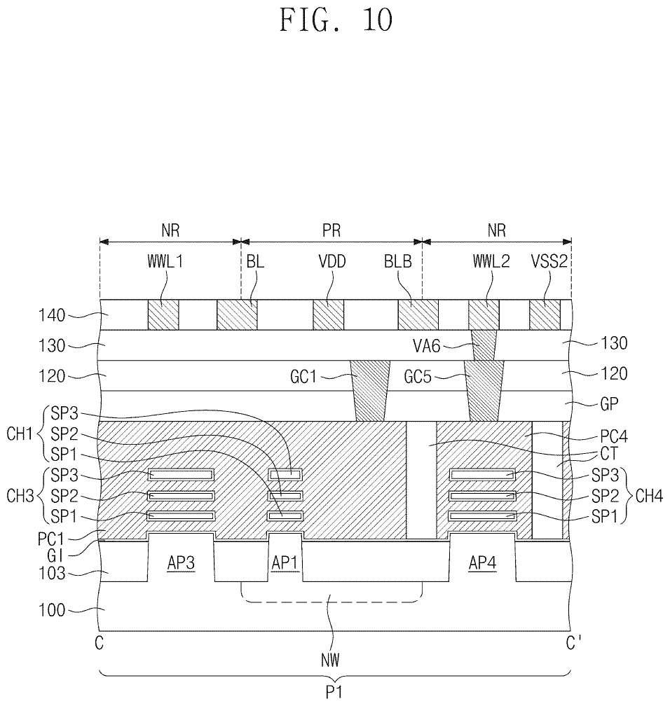

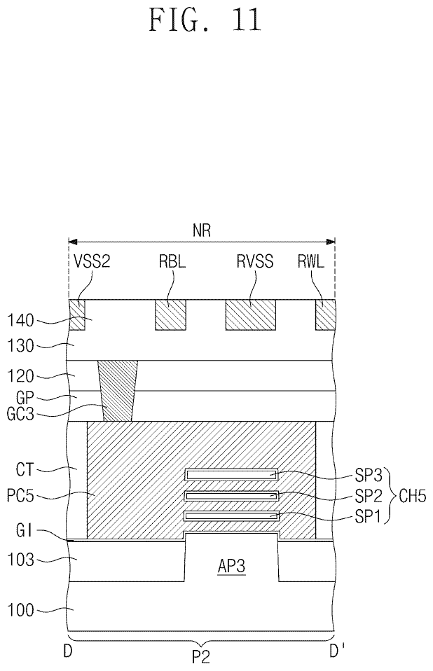

FIG. 9, FIG. 10, and FIG. 11 are cross-sectional views of semiconductor devices according to embodiments of the inventive concept, respectively, taken along lines A-A′, C-C′, and D-D′ of FIG. 4.

According to embodiments, the transistors constituting the SRAM cell 10 of FIG. 1 may be a three-dimensional field effect transistor (e.g., multi bridge channel field effect transistor (MBCFET), a gate-all-around field effect transistor (GAAFET)) in which a gate electrode three-dimensionally surrounds a nanowire channel or nanosheet channel, or a fin field-effect transistor (Fin FET). In some embodiments, the SRAM cell 10 may include eight transistors.

In detail, referring to FIG. 4, FIG. 9, FIG. 10, and FIG. 11, first to fifth channel patterns CH1 to CH5 may be disposed on first to fifth active patterns AP1 to AP5, respectively. Each of the first to fifth channel patterns CH1 to CH5 may include a first semiconductor pattern SP1, a second semiconductor pattern SP2, and a third semiconductor pattern SP3 that are spaced apart from each other in a third direction D3 and are sequentially stacked. In some embodiments the first to fifth channel patterns CH1 to CH5 may include a different number of semiconductor patterns. For example, the first to fifth channel patterns CH1 to CH5 may include four semiconductor patterns disposed in a stack.

Each of gate electrodes (e.g., fifth gate electrode PC5) may include a first inner electrode PO1 interposed between the corresponding active pattern and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

A gate insulating layer GI may be interposed between the gate electrodes and first to fifth channel patterns CH1 to CH5. For example, the gate insulating layer GI may cover an upper surface, a bottom surface, and sidewalls of each of the first to third semiconductor patterns SP1, SP2, and SP3. The gate insulating layer GI may be interposed between the first inner electrode PO1 and the corresponding active pattern.

The first to fifth channel patterns CH1 to CH5 may be disposed between the first source/drain patterns SD1 or between the second source/drain patterns, respectively.

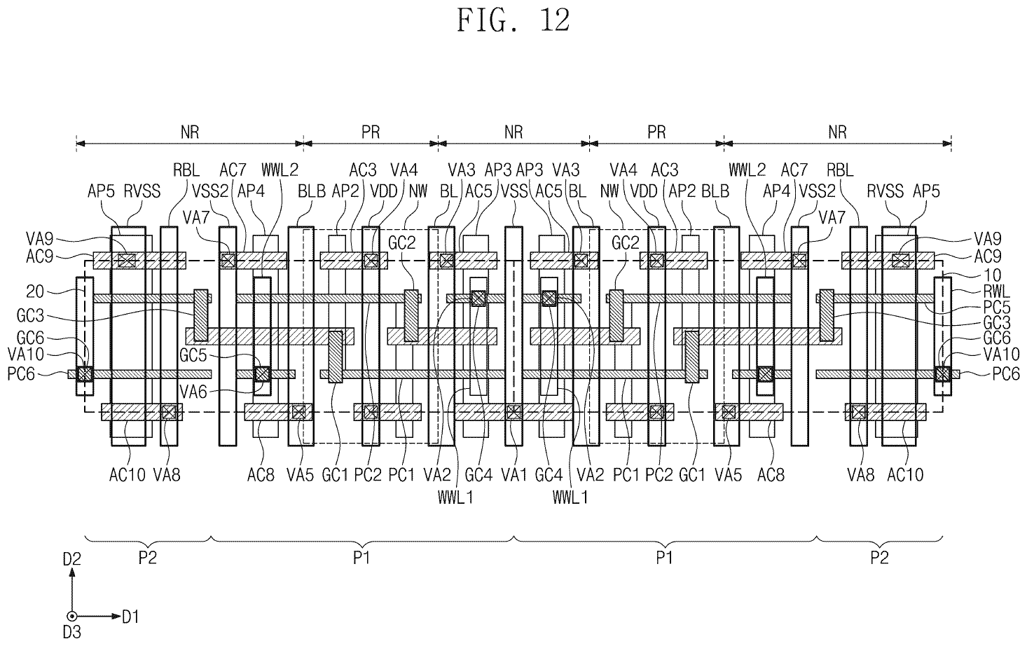

FIG. 12 is a plan view showing a semiconductor device according to embodiments of the inventive concept.

Referring to FIG. 12, a semiconductor device may include a plurality of SRAM cells. As an example, a first SRAM cell 10 and a second SRAM cell 20 may be integrated on a semiconductor substrate 100.

The first and second SRAM cells 10 and 20 may be adjacent to each other in the first direction D1, and each of the first and second SRAM cells 10 and 20 may include a first port P1 and a second port P2. Each of the first SRAM cell 10 and the second SRAM cell 20 may include the transistors described with reference to FIGS. 1 to 8.

The first SRAM cell 10 may be substantially the same as the SRAM cell 10 described with reference to FIGS. 1 to 8.

The second SRAM cell 20 is substantially the same as the SRAM cell 10 described with reference to FIGS. 1 to 8, but may be arranged in mirror symmetry with the first SRAM cell 10. The first and second SRAM cells 10 and 20 may share the first ground line VSS1.

According to embodiments of the inventive concept, in the SRAM cell including the first port and the second port, the first and fourth gate electrodes PC1 and PC4 disposed and the second and third gate electrodes PC2 and PC3 in the first port may be disposed to be point symmetrical to each other. Accordingly, the transistors forming the first inverter and the second inverter may have substantially the same operating characteristics. That is, the first pull-down transistor and the second pull-down transistor may be inhibited or prevented from having asymmetric operation characteristics, for example, having different threshold voltages.

Additionally, the first port and the second port may be connected to each other through the gate contact connected to the gate terminals of the first pull-up and first full-down transistors, the active contact connected to the drain terminals of the second pull-up and second pull-down transistors, and the gate contact connected to the gate electrode of the pull-down transistor of the second port.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor device comprising:
a first gate electrode controlling a first pull-down transistor and a first pull-up transistor;
a second gate electrode controlling a second pull-down transistor and a second pull-up transistor;
a third pull-down transistor;
a third pass transistor connected in series with the third pull-down transistor;
a first node active contact connecting a drain terminal of the second pull-up transistor and a drain terminal of the second pull-down transistor;
a first gate contact connecting a gate terminal of the third pull-down transistor and the first node active contact; and
a second gate contact connecting a gate terminal of the first pull-up transistor and a gate terminal of the first pull-down transistor to the first node active contact.

2. The semiconductor device of claim 1, wherein the first gate electrode has a same length as the second gate electrode in a first direction.

3. The semiconductor device of claim 1, further comprising a second node active contact connecting a drain terminal of the first pull-up transistor and a drain terminal of the first pull-down transistor.

4. The semiconductor device of claim 3, wherein the first node active contact and the second node active contact each extend between the first gate electrode and the second gate electrode in a first direction parallel to the first gate electrode and the second gate electrode.

5. The semiconductor device of claim 4, wherein each of the first gate contact and the second gate contact each has a long axis in a second direction intersecting the first direction.

6. The semiconductor device of claim 3, further comprising a third gate contact connecting the second node active contact and the second gate electrode.

7. The semiconductor device of claim 1, further comprising:
a first pass transistor connected to a drain terminal of the first pull-up transistor and a gate terminal of the second pull-up transistor; and
a second pass transistor connected to a drain terminal of the second pull-up transistor,
wherein a gate terminal with the first pass transistor is electrically connected to a gate terminal of the second pass transistor.

8. The semiconductor device of claim 1, further comprising:
a semiconductor substrate including a first active region and a second active region;
a first active pattern and a second active pattern disposed in the first active region; and
a third active pattern, a fourth active pattern, and a fifth active pattern disposed in the second active region,
wherein the third active pattern and the fourth active pattern are spaced apart from each other in a first direction with the first active pattern and the second active pattern interposed therebetween,
wherein the fifth active pattern is disposed on a side of the fourth active pattern,
wherein the first gate electrode is disposed across the first active pattern and the third active pattern, and
wherein the second gate electrode is disposed across the second active pattern and the fourth active pattern.

9. The semiconductor device of claim 8, further comprising a fifth gate electrode and a sixth gate electrode disposed spaced apart from each other across the fifth active pattern,
wherein the fifth gate electrode is connected to the gate terminal of the third pull-down transistor,
wherein the sixth gate electrode is connected to a gate terminal of the third pass transistor, and
wherein the fifth gate electrode and the sixth gate electrode have different lengths in the first direction.

10. The semiconductor device of claim 8, further comprising a plurality of channel patterns stacked on each of the first active pattern, the second active pattern, the third active pattern, the fourth active pattern, and the fifth active pattern, the plurality of channel patterns vertically spaced apart from each other,
wherein the first gate electrode surrounds the channel patterns on the first active pattern and the third active pattern, and
wherein the second gate electrode surrounds the channel patterns on the second active pattern and the fourth active pattern.

11. A semiconductor device comprising:
a first port including a first inverter, a second inverter cross-coupled to the first inverter, a first pass transistor connected between a bit line and an input node of the first inverter, and a second pass transistor connected between a complementary bit line and an input node of the second inverter; and
a second port including a read pull-down transistor having a gate connected to the input node of the first inverter and an output node of the second inverter, and a third pass transistor connected between the read pull-down transistor and a read bit line.

12. The semiconductor device of claim 11, wherein, in the first port, the first inverter and the second inverter are symmetrically integrated on a semiconductor substrate.

13. The semiconductor device of claim 11, further comprising:
a first node active contact connected to the output node of the second inverter;
a first gate contact connecting the gate of the read pull-down transistor and the first node active contact; and
a second gate contact connecting the input node of the first inverter and the first node active contact.

14. The semiconductor device of claim 11, wherein each of the first inverter and the second inverter, the first pass transistor, the second pass transistor, and the third pass transistor, and the read pull-down transistor is configured as one of a gate-all-around field effect transistor (GAAFET), a multi bridge channel field effect transistor (MBCFET), or Fin FET.

15. A semiconductor device comprising:
a semiconductor substrate including a first active region and a second active region;
a first active pattern and a second active pattern disposed on the first active region;
a third active pattern, a fourth active pattern, and a fifth active pattern disposed on the second active region, wherein the third active pattern and the fourth active pattern are spaced apart from each other in a first direction with the first active pattern and the second active pattern interposed therebetween, and the fifth active pattern is disposed on a side of the fourth active pattern;
a first gate electrode crossing the first active pattern and the third active pattern and having a first length in the first direction;
a second gate electrode crossing the second active pattern and the fourth active pattern and having a second length substantially equal to the first length in the first direction;
a third gate electrode spaced apart from the second gate electrode in the first direction and crossing the third active pattern;
a fourth gate electrode spaced apart from the first gate electrode in the first direction and crossing the fourth active pattern;
a fifth gate electrode spaced apart from the second gate electrode in the first direction and crossing the fifth active pattern;
a sixth gate electrode spaced apart from the fourth gate electrode in the first direction and crossing the fifth active pattern;
a first node active contact connected to source/drain patterns on the second active pattern and the fourth active pattern disposed between the first gate electrode and the second gate electrode;
a first gate contact connecting the first gate electrode and the first node active contact; and
a second gate contact connecting the fifth gate electrode and the first node active contact.

16. The semiconductor device of claim 15, wherein the first gate electrode and the first gate contact are disposed symmetrical with the second gate electrode and the second gate contact.

17. The semiconductor device of claim 15, wherein the first gate contact and the second gate contact have long axes in a second direction intersecting the first direction.

18. The semiconductor device of claim 15, further comprising:
a second node active contact connected to the source/drain patterns of the first active pattern and the third active pattern disposed between the first gate electrode and the second gate electrode; and
a third gate contact connecting the second node active contact and the second gate electrode.

19. The semiconductor device of claim 15, wherein the fifth gate electrode and the sixth gate electrode have different lengths in the first direction.

20. The semiconductor device of claim 15, wherein each of the first active pattern and the second active pattern has a first width in the first direction,
wherein each of the third active pattern and the fourth active pattern has a second width greater than the first width in the first direction,
wherein the fifth active pattern has a third width greater than the second width in the first direction.
